(19) United States
(12) Patent Application Publication
(10) Pub. No.: US 2009/0014045 A1
(43) Pub. Date: Jan. 15, 2009

(54) Appliance for cell-phones, laptops and PDAs

(76) Inventors: Tilda Hines, Stamford, CT (US); David E. Orr, Vancouver, WA (US)

Correspondence Address: David E. Orr, 4616 NE 134th Street, Vancouver, WA, 98686, US

(21) Appl. No.: 11/827,771

(22) Filed: Jul. 13, 2007

(51) Int. Cl. H01L 35/28

(52) U.S. Cl. 136/200

(57) ABSTRACT

In a first aspect of the invention, a power source comprising an electrical charging device comprising a thermal conductor, a thermoelectric source (TES) for converting thermal energy into electrical energy, and a battery for accumulating electrical charge generated by the converter. The battery provides electrical power to a cell-phone, laptop computer or the like. In a second aspect of the invention, an RFID tag is attached to the cell-phone, laptop or the like to prevent loss or theft.

### FIELD

The present invention relates an appliance for personal communications accessories; more specifically the present invention is an appliance comprising: (1) a charger for cell-phones, laptops and personal digital assistants, the appliance deriving electrical power by thermo-electrical means, and (2) a locator for keeping track of these same personal communications devices.

### BACKGROUND

There are over 1 billion portable personal computing and communications devices in use today. All these devices- cell phones, laptop computers and PDA (personal digital assistants) rely upon batteries as power sources. What is needed is a reliable, inexpensive charging source for these batteries, while at the same time keeping track of these devices to prevent loss or theft.

### SUMMARY

In response to the need for a cheap and effective power source for cell-phones, laptops and the like, herein is disclosed, in a first aspect, a power source comprising an electrical charging device comprises a thermal conductor, a thermoelectric source (TES) for converting thermal energy into electrical energy, and a battery for accumulating electrical charge generated by the converter.

The electrical charging device may be configured to be carried by a person, and by absorbing heat from the person's by body, and by the Seebeck effect, provide electricity to, and charge an electrical device carried by the person.

Also, the device may be used in conjunction with a laptop computer and, by absorbing heat energy from the computer, partially or fully charge the computer.

The invention, as disclosed in the first aspect, will be seen to have a number of advantages and benefits; among these is the ultimate convenience of not running out of power at an inopportune time.

Another advantage is utilizing free and readily available heat as a source creating electricity.

In a second aspect, the invention comprises an RFID (radio-frequency-identifier) signal responder that is attached to the cell-phone, laptop or the like, and an RFID signal generator, that is retained by the owner of the cell-phone, laptop, or the like. The RFID signal generator creates an alarm or signal when the cell-phone, laptop or the like is left behind or is moved greater than a certain pre-defined distance from the signal generator.

The second aspect of the invention will be seen to have a number of benefits and advantages, among, the second aspect of the invention prevents theft or inadvertent loss the of the cell-phone, laptop or the like.

The benefits and advantages of the invention will appear from the disclosure to follow. In the disclosure reference is made to the accompanying drawings, which form a part hereof and in which is shown by way of illustration a specific embodiment in which the invention may be practiced. This embodiment will be described in sufficient detail to enable those skilled in the art to practice the invention, and it is to be understood that other embodiments may be utilized and that structural changes may be made in details of the embodiments without departing from the scope of the invention.

### BRIEF DESCRIPTION OF THE DRAWINGS

FIG. 1 shows the relationship of Seebeck coefficients in relations to charge carrier concentration.

FIG. 2 is a chart showing the relationship of ZT versus temperature for various semiconductor materials.

FIG. 3 is a diagram of an exemplary thermo-electrical device.

FIG. 4 shows a view of the components of the power source..

FIG. 5 shows the components of the power source in a holder having a battery charged by the thermo-electrical effect.

FIG. 6 shows a second view of the components of the power source in a holder having a battery charged by the thermo-electrical effect.

FIG. 7 shows the power source used with a laptop.

FIG. 8 shows the power source used with a cell-phone.

FIG. 9 shows an implementation of the invention as a semiconductor mesh.

FIG. 10 is a further view of the semiconductor mesh.

FIG. 11 is a further view of the semiconductor mesh showing holes drilled in order to effect a semiconductor utilizing heat energy.

FIG. 12 is a further second view of the semiconductor mesh showing holes drilled in order to effect a semiconductor utilizing heat energy.

FIG. 13 shows the semiconductor materials comprising the mesh.

FIG. 14 illustrates the second aspect of the invention comprising a passive RFID tag mounted to a cell-phone or keys.

FIG. 15 illustrates an RFID chip attached to a mount, which in turn fastens the RFID chip to an object.

FIG. 17 is a flow chart representing the alarm logic of a reader interrogating an RFID chip.

### DETAILED DESCRIPTION

A first Aspect of the Invention

### The Seebeck Effect and Thermoelectricity

It is known that a voltage was developed in a loop containing two dissimilar metals, provided the two junctions are maintained at different temperatures. It is also known that electrons moving through a solid can carry heat from one side of the material to the other side. The true nature of this effect was explained later that upon flow of current, heat is absorbed or generated between two conductors. This has been demonstrated by freezing a drop of water at a bismuth-antimony junction and melting the ice by reversing the current.

In a thermoelectric device, a flow of charge carriers pumps heat from one side of the material to the other. The ratio of heat flow to current for a particular material is known as the Peltier coefficient, π. Its value is closely related to another intrinsic property, the Seebeck coefficient, S. The British physicist Thomson (Lord Kelvin) established a relationship between the Seebeck and Peltier coefficients and predicted the third thermoelectric effect, the Thomson effect. This effect relates to the heating or cooling in a single homogenous conductor when a current passes along it in the presence of a temperature gradient. These three effects are connected to each other by a simple relationship:

S=π/τ

When a thermal gradient, T, is applied to a solid, the gradient will cause an electric field, V, in the opposite direction; this is known as Seebeck effect. The ratio V/T is defined as the Seebeck coefficient (S), and is expressed in volts per degree, or more often micro-volts per degree, μV/K. The metals best suited for thermoelectric applications have highest Seebeck coefficients about 10 μV/K or less, yielding generating efficiencies of 1%, which are uneconomical as a source of electrical power, but enough to be used for temperature sensing, as thermocouples. Metal thermocouples generate tens of micro-volts per degree temperature difference and it is very familiar temperature controlling sensors in domestic refrigerators and central heating systems.

### Thermo-Electric Materials

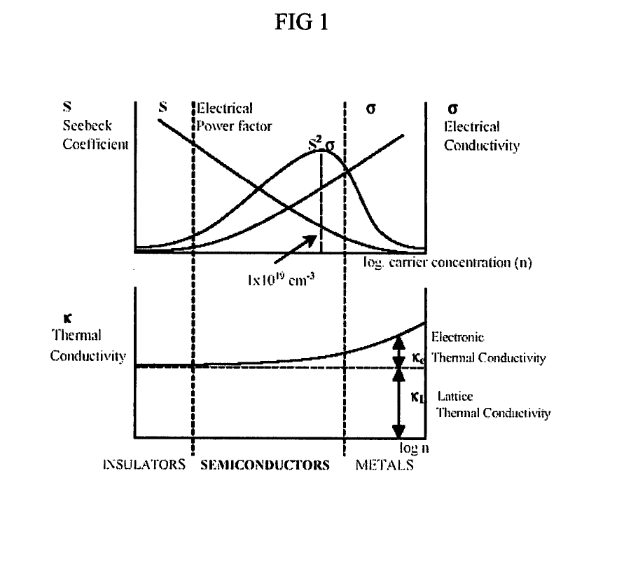

Thermoelectric properties for a material depends upon the carrier concentration as shown in FIG. 1. Metals are poor thermoelectric materials with a low Seebeck coefficient, because they have large electronic contribution to thermal conductivity, so σ and κ will cancel each other. Insulators have a high Seebeck coefficient, and a small electronic contribution to thermal conductivity, but their charge density and therefore electrical conductivity are low leading to a low thermoelectric effect. The best thermoelectric materials are those between metals and insulators; i.e. semiconductors with an electronic density of 10¹⁹/cm₃, (refer to FIG. 1.)

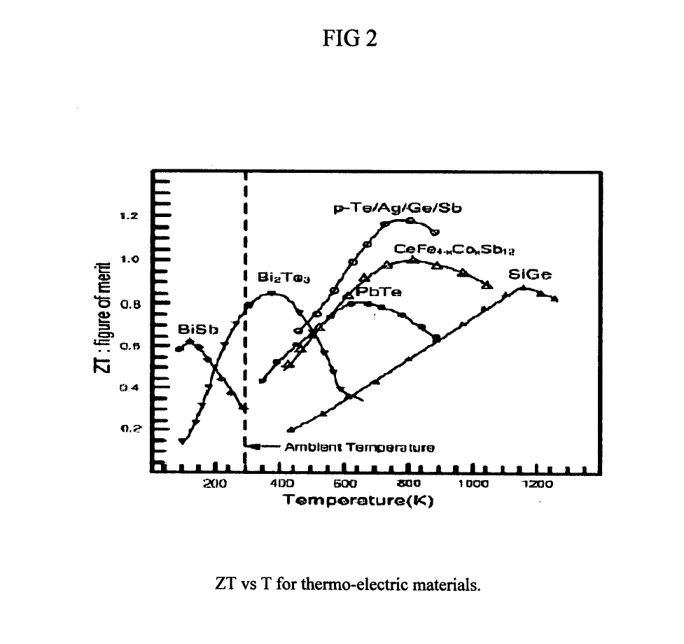

The electrical properties of semi-conducting materials can change dramatically with temperature. As a result, semiconductors can only function as thermoelectric materials over certain temperature ranges, which will vary for each semiconductor. FIG. 2 shows the effectiveness of most commonly used semiconductor materials for thermoelectric devices, as measured by the figure of merit (ZT). Higher ZT yields better thermoelectric performance. Known thermoelectric materials fall into three categories depending upon their temperature range of operation, as shown in FIG. 2. Bismuth telluride and its alloys have the highest ZT, and are extensively employed in terrestrial cooling. The most commonly used semiconductor material for cooling applications, Bismuth Telluride system (Bi₂Te₃), has a maximum performance at approximately 120° C. with an effective operating range (EOR) of −100° C. to +200° C. Bi—Sb alloys are useful only at low temperatures. Lead Telluride (PbTe), the next most commonly used material, is typically used for power generation but is not as efficient as Bi²Te³ in cooling applications. PbTe reaches a peak ZT at 390° C. and has an EOR of 200 to 900° C. PbTe is typically used for power generation because its higher operating temperatures yields more efficient power generation when the heat is rejected at ambient temperatures. TAGS refers to the alloys (TESe)₁₋ₓ(AgSbTe)ₓ, where x ˜0.2, and has an EOR of 400-1000° C. Silicon Geranium, SiGe, has an EOR of 1200-1000° C. and have been widely used in thermoelectric generators for space applications together with TAGS. The Skutterudite, CeFe³CoSb¹², has an EOR of 400 to 1100° C. but is not used in practice since TAGS is superior in the same temperature range.

### Semiconductors as Thermo-Electric Sources

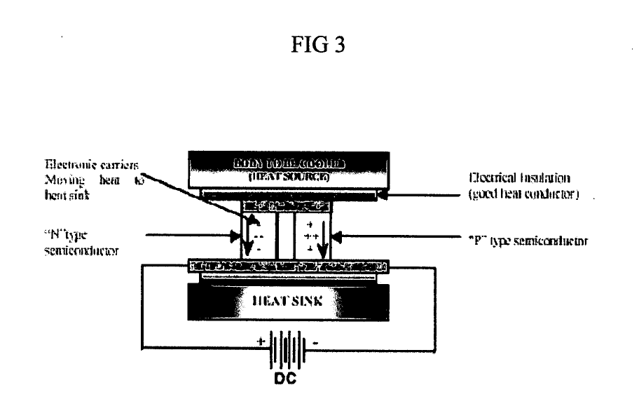

A TES couple/module may comprise n- and p-type thermoelectric materials, as shown in FIG. 3, where n and p stands respectively for the negative and positive types of charge carriers within the material, n for electrons, and p for holes. The working principle of a typical TES couple is, as the electrons move from the p-type material to the n-type material through an electrical connector, the electrons jump to a higher energy state absorbing thermal energy (cold side). Continuing through the lattice of material, the electrons flow from the n-type material to the p-type material through an electrical connector, dropping to a lower energy state and releasing energy as heat to the heat sink (hot side).

With reference to FIG. 3, the thermoelectric source operates as a heat engine utilizing electrons in the thermo-elements as the working fluid rather than a gas or vapor. The TES consists of a p-type and a n-type element of thermoelectric material, which generates electrical current upon exposure to a temperature difference. The elements are arranged electrically in series and thermally in parallel. By means of combining a p- and n-type semiconductor, voltage and therefore electrical power are generated. Because the thermo-power, S, has opposite sign for p- and n-type materials, contributions from both elements are adding to nearly double the generator voltage as that of a single element. Besides a high thermo-power, for an efficient energy conversion high electrical and low thermal conductivity, s and k, respectively are required. Hence, the decisive material parameter for the thermoelectric conversion material is ZT.

### An Exemplary Embodiment of the First Aspect of the Invention

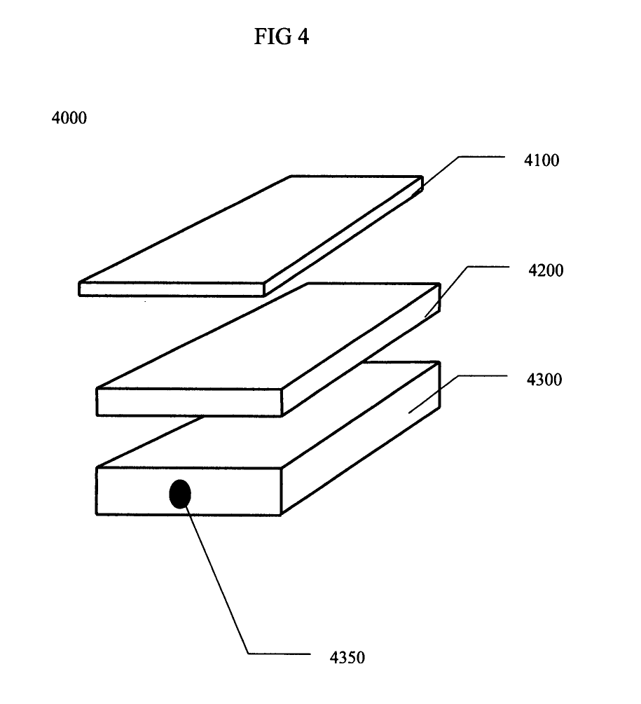

With reference to FIG. 4, the electrical charging device 4000 comprises a thermal conductor 4100, a thermo-electric source (TES) 4200 for converting thermal energy into electrical energy, and a battery 4300 for accumulating electrical charge generated by the converter 4200.

Referring to FIG. 4, the thermal conductor 4100 is made from a material having a high heat capacity, such as copper or steel or brass. The thermoelectric source (TES) 4200 converts heat energy into electrical energy by the Seebeck effect, and is in electrical communication with the battery 4300, which stores charge from the TES. The battery has plug receptor 4350 for receiving a plurality of plugs, which are adapted to fit the electrical charging inlet of various cell phones and laptop computers.

The TES may utilize existing semiconductor devices, such as the Watronix, Inc. nbS1-071.021 or similar chips that convert heat into electricity.

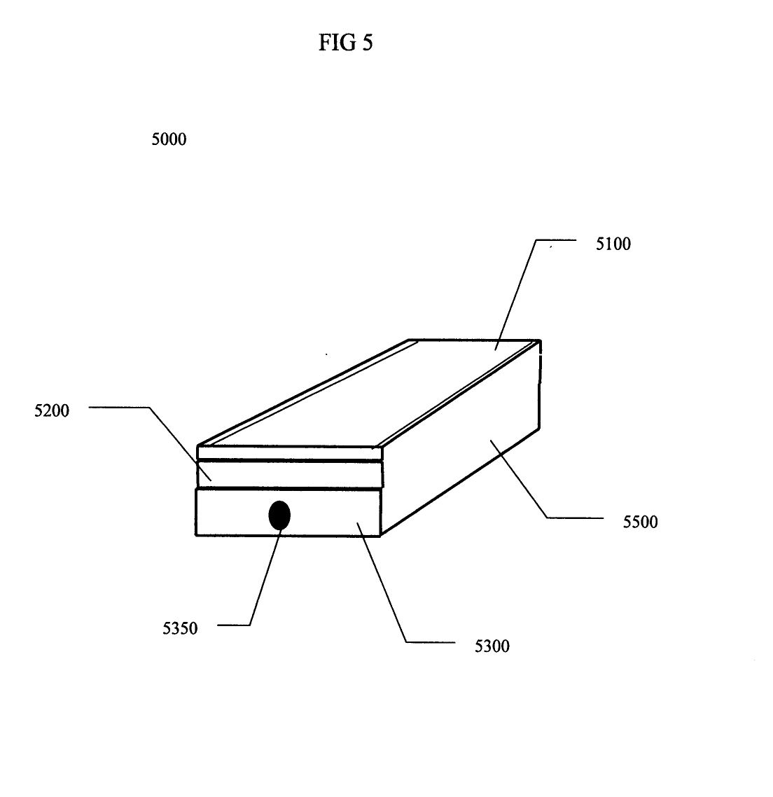

With reference to FIG. 5, the electrical charging device 5000 is shown with components enclosed in a case or holder 5500, the enclosure holding the thermal conductor 5100, the TES 2200 and the battery 5300.

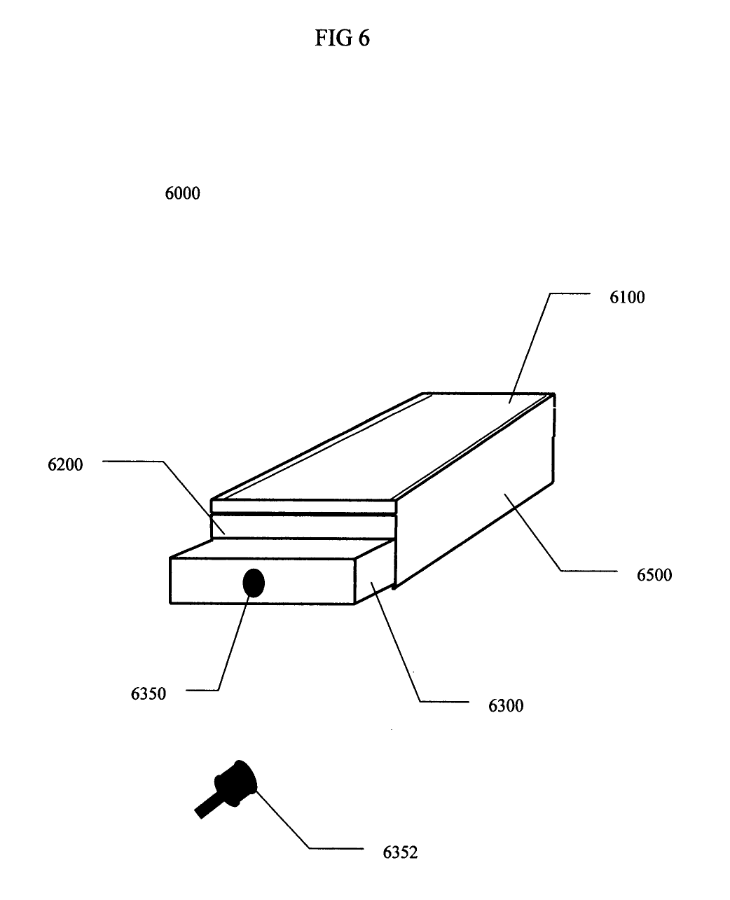

With reference to FIG. 6, the battery 6300 is removed from the enclosure 6500 after being charged by the TES 6200. A plug 6352 is shown ready to plug into the plug receptor 6350; the plug 6352 is adapted to a particular device, such as a cell-phone, laptop computer, PDA, etc., that will be charged by the battery 6300. Heat sources

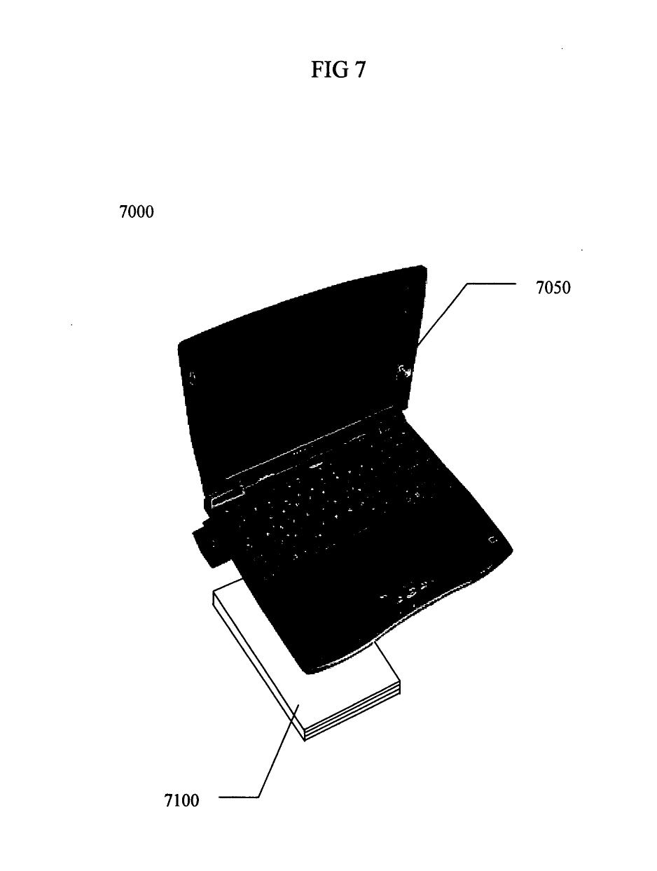

FIG. 7 shows the electrical charging device 7100 placed under a laptop computer 7050, from which heat is absorbed by the thermal conductor of the electrical charging device 7100.

The electrical charging device 7100 can be placed in contact with a variety of heat sources, including desk-top computers, in the windows of building and vehicles where it will received direct sunlight.

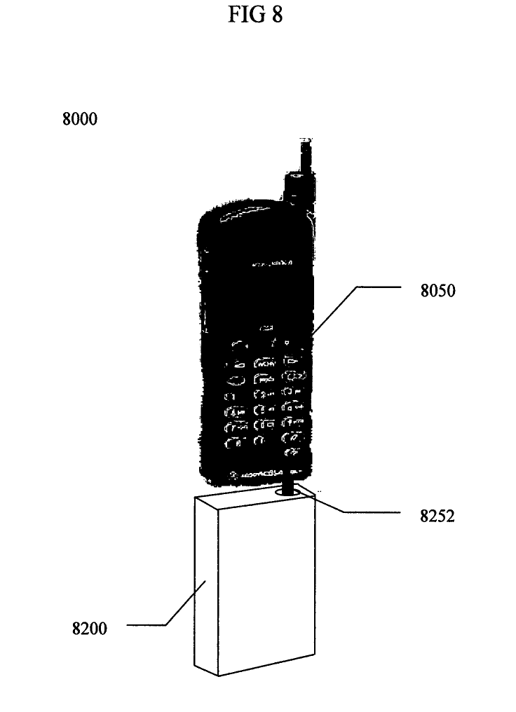

Referring to FIG. 8, the battery 8200 of the electrical charging device is shown fitted with a plug 8252 suitable for charging a cell phone 8050.

### A Second Embodiment of the First Aspect of the Invention

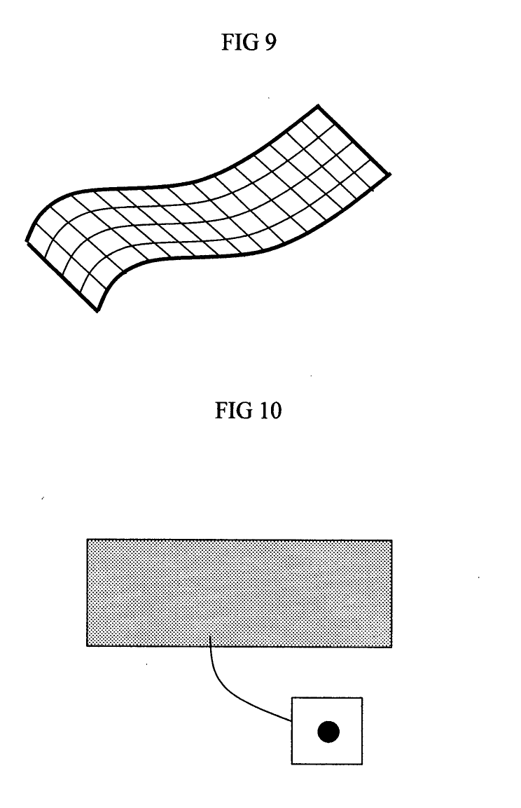

FIG. 9 shows a second embodiment, the second embodiment based upon a semiconductor mesh that is made in the form of a flexible mat. The mat can be folded or laid flat and placed under a laptop computer or laid upon the dashboard of an automobile beneath a windshield, where sunshine provides a heat source (see the description above.)

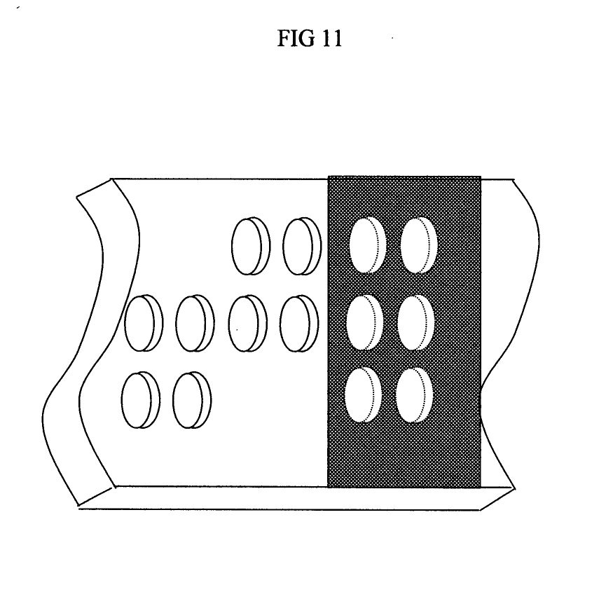

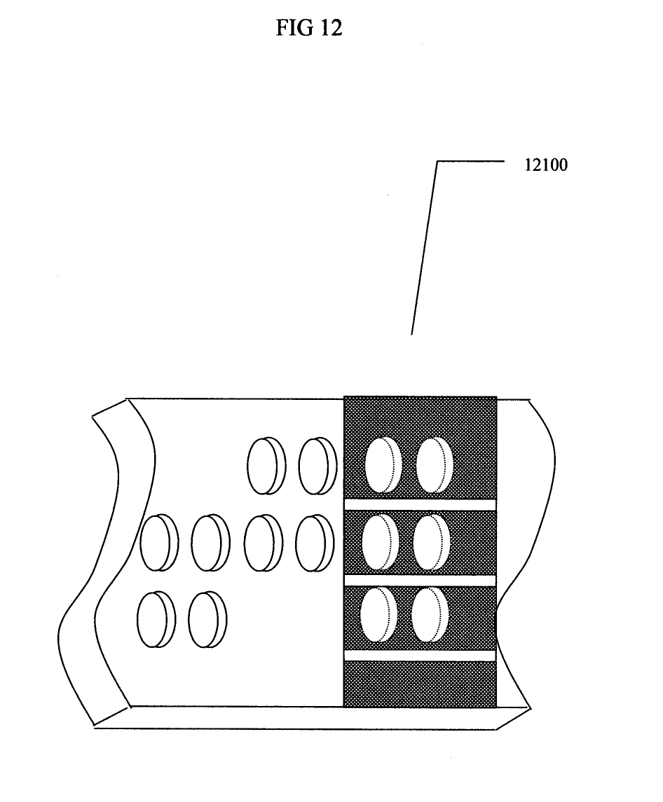

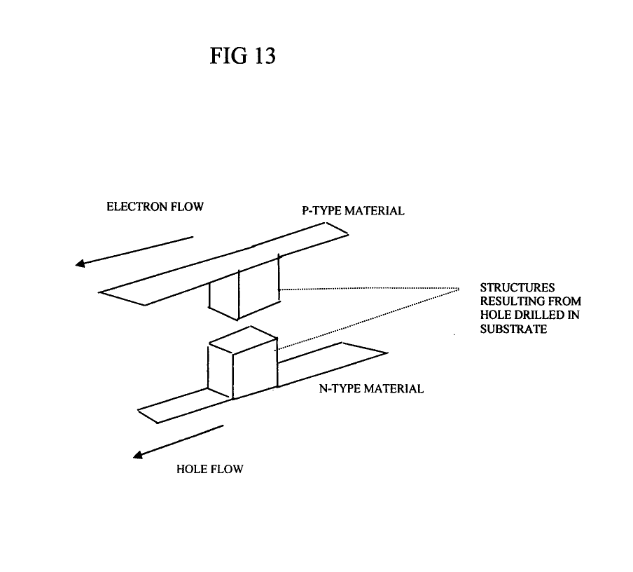

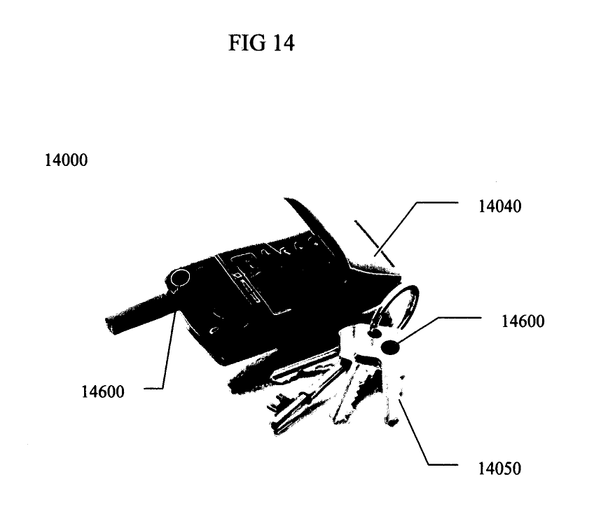

The semiconductor mesh is fashioned as nano-wires, and is made by the following process:
1. A first non-conducting substrate is first created; for example a pure silicon substrate.
2. Microscopic holes are drilled through the first substrate using a laser (see FIG. 10). FIG. 10 shows an illustration of a single hole drilled among many holes made in the substrate.
3. The first substrate is placed in a vacuum chamber and a p-type material is vacuum deposited on the first substrate. The p-type material is deposited on both sides of the first substrate and into, and filling, the holes drilled by the laser (see FIG. 11).
4. A mask substrate is deposited onto both sides of the first substrate (see FIG. 12).
5. Using photolithography techniques, the mask substrate is etched to produce the pattern shown in FIG. 12. In FIG. 12, the effect of the etching is to produce a sequence of “bumps” (p-type material) connected by thin strips (nano-wires) that are also p-type material.
6. Steps 1-2 are duplicated using a second substrate.
7. The second substrate is placed in a vacuum chamber and a n-type material is vacuum deposited on the second substrate. The n-type material is deposited on both sides of the second substrate and into, and filling, the holes drilled by the laser (see FIG. 10).
8. A mask substrate is deposited onto both sides of the second substrate (see FIG. 11).
9. Using photolithography techniques, the mask substrate is etched to produce the pattern shown in FIG. 12.
10. The two substrates are placed and held together to produce a TES array, as shown in FIG. 13. The effect of the two substrates placed and held together is to create a series of elements that will amplify electrical current produced by thermal effects.

### A Second Aspect of the Invention

In the second aspect of the invention, the appliance is used to prevent the loss or theft of the cell phone, or PDA.

### RFID

Microelectronics has made possible the use of low-cost, reliable transponder systems for electronic identification. Such transponder systems are often referred to as RFID tags, as it is generally assumed that their primary end application will be that of tagging a variety of goods. In the interest of cost savings and miniaturization, RFID tags are generally manufactured as integrated circuits.

An RFID system may consist of several components: tags, tag readers, edge servers, middleware, and application software. The purpose of an RFID system is to enable data to be transmitted by a mobile device, called a tag, which is read by an RFID reader and processed according to the needs of a particular application. The data transmitted by the tag may provide identification or location information, or specifics about the product tagged, such as price, color, date of purchase, etc. The use of RFID in tracking and access applications first appeared in 1932 and was used to identify friendly and unfriendly aircraft. RFID quickly gained use because of its ability to track moving objects.

### Passive RFID Tags

Passive RFID tags have no internal power supply. The minute electrical current induced in the antenna by the incoming radio frequency signal provides just enough power for the CMOS integrated circuit (IC) in the tag to power up and transmit a response. Most passive tags signal by backscattering the carrier signal from the reader. This means that the aerial (antenna) has to be designed to both collect power from the incoming signal and also to transmit the outbound backscatter signal. The response of a passive RFID tag is not just an ID number (GUID); the tag chip can contain nonvolatile EEPROM for storing data. Lack of a power supply means that the device can be quite small: commercially available products exist that can be embedded under the skin. As of 2006, the smallest such devices measured 0.15 mm×0.15 mm, and are thinner than a sheet of paper (7.5 micrometers). The addition of the antenna creates a tag that varies from the size of postage stamp to the size of a post card. Passive tags have practical read distances ranging from about 2 mm (ISO 14443) up to a few meters (EPC and ISO 18000-6) depending on the chosen radio frequency and antenna design/size. Due to their simplicity in design they are also suitable for manufacture with a printing process for the antennas. Passive RFID tags do not require batteries, can be much smaller, and have an unlimited life span.

### Semi-Passive RFID Tags

Semi-passive RFID tags are similar to passive tags except for the addition of a small battery. This battery allows the tag IC to be constantly powered, which removes the need for the aerial to be designed to collect power from the incoming signal. Aerials can therefore be optimized for the back-scattering signal. Semi-passive RFID tags are thus faster in response, though less reliable and powerful than active tags.

### Active RFID Tags

Unlike passive RFID tags, active RFID tags have their own internal power source which is used to power any ICs that generate the outgoing signal. Active tags are typically much more reliable (e.g. fewer errors) than passive tags due to the ability for active tags to conduct a communications session with a reader. Active tags, with their onboard power supply, also transmit at higher power levels than passive tags, allowing them to be more effective in “RF challenged” environments, or at longer distances. Many active tags have practical ranges of hundreds of meters, and a battery life of up to 10 years. Some active RFID tags include sensors such as temperature logging. Other sensors that have been married with active RFID include humidity, shock/vibration, light, radiation, temperature and atmospherics. Active tags typically have much longer range (approximately 300 feet) and larger memories than passive tags, as well as the ability to store additional information sent by the transceiver. At present, the smallest active tags are about the size of a coin and sell for a few dollars.

### RFID Systems

In a typical RFID system, individual objects are equipped with a small, inexpensive tag. The tag contains a transponder with a digital memory chip that is given a unique electronic product code. The interrogator, an antenna packaged with a transceiver and decoder, emits a signal activating the RFID tag so it can read and write data to it. When an RFID tag passes through the electromagnetic zone, it detects the reader's activation signal. The reader decodes the data encoded in the tag's integrated circuit (silicon chip) and the data is passed to the host computer. The application software on the host processes the data, often employing Physical Markup Language (PML).

Take the example of securing books in a library. Security gates can detect whether or not a book has been properly checked out of the library. When users return items, the security bit is re-set and the item record in the library computer system is automatically updated. In some RFID solutions a return receipt can be generated. At this point, materials can be roughly sorted into bins by the return equipment.

### An Exemplary Embodiment of the Second Aspect of the Invention

In an exemplary embodiment of the second aspect of the invention, the appliance comprises an RFID chip or tag that is attached to an object, such as cell phone or even glasses or purse. A transmitter device polls or interrogates the RFID tag. As long as the interrogator or reader receives a signal it remains silent.

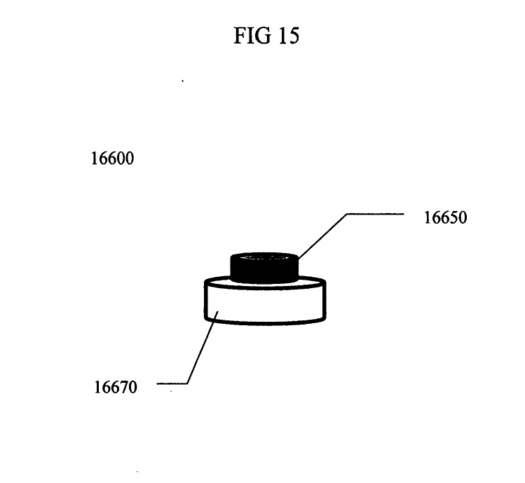

FIG. 14 shows an implementation 14000 of the second aspect of the invention comprising an RFID signaling device 14600 attached to a cell phone 14040 of to a set of keys 14050.

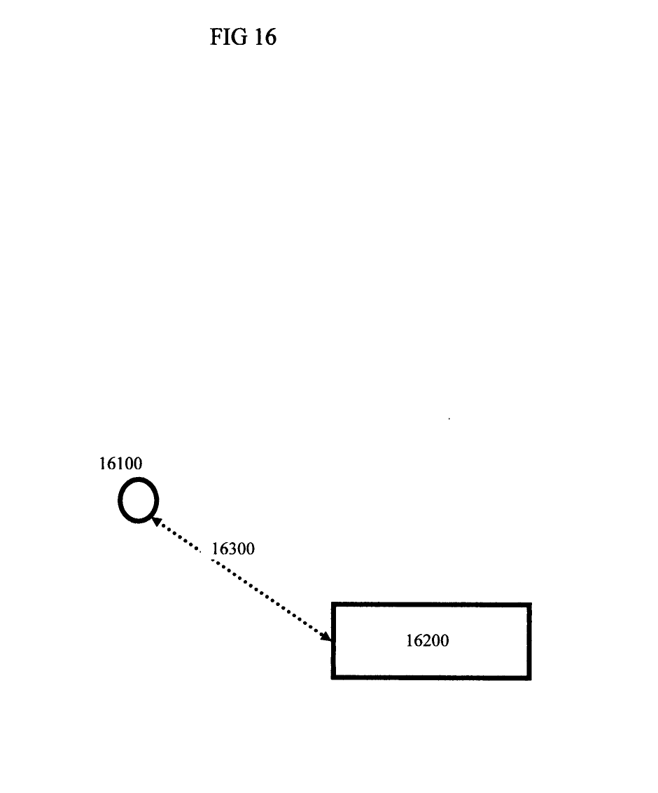

FIG. 15 depicts the RFID receiver/transmitter 15600 comprising an RFID tag 15650 and a means 15670 for attachment of the RFID tag 15650 to an object. In this example, the RFID tag 16650 is attached to a mount 16670, which in turn may be attached to an object.

With reference to FIG. 16, an exemplary embodiment of the second aspect of the invention comprising an RFID tag 16100 configured or made to respond to a predetermined frequency 16300 emitted by an interrogator (reader) 16200. In turn the interrogator 16200 is made to emit an audible signal, when the interrogator fails to receive a signal from the passive RFID tag.

Therefore, in practice, the RFID tag 16100 is attached to an object, and is polled or interrogated by the reader 16200. As long as the object is within range of the RFID tags signal range, the reader will not emit a sound. However, if the reader 16200 is unable to receive a signal from the RFID tag 16100, it will sound an alarm notifying a user the object is out of range.

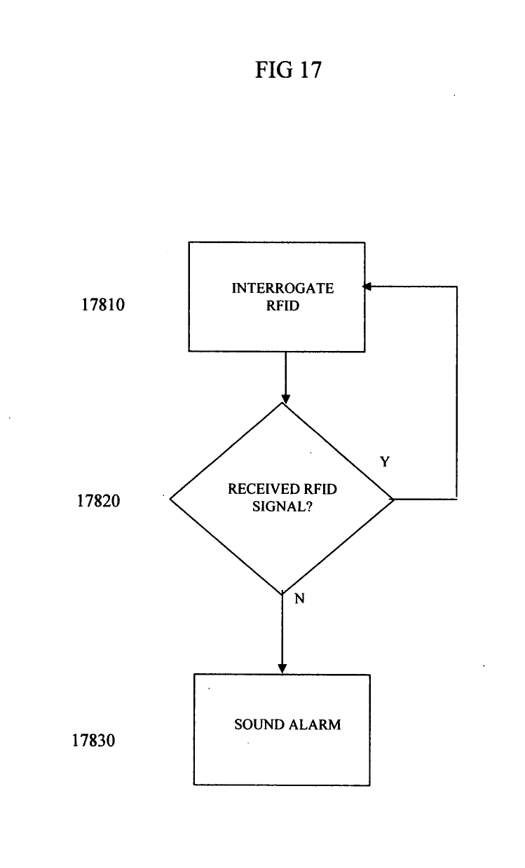

With reference to FIG. 17, the interrogator interrogates 16810 the RFID tag by sending a signal of a predetermined frequency that is recognized by the RFID tag. If the RFID is in range and is capable of responding, the RFID tag responds 16820, or not. If the reader does not receive acknowledgement, the reader sounds an alarm 16830.

### DISCLOSURE SUMMARY

A single exemplary embodiment and a variant of the embodiment of a first aspect of the invention, and a single embodiment of a second aspect of the invention have been disclosed. It will be appreciated that the embodiment and its variant are directed to a bathtub enclosure appliance that is functional, decorative, and easy to install.

The full scope and description of the invention is given by the claims that follow.

What is claimed is:

1. A device for charging an electric appliance carried by a person, the device worn by the person, the device receiving heat from the person's body and by the Seebeck effect electrically charging the electric appliance.

2. A device for charging a computer laptop, the device receiving heat from the laptop and electrically charging the laptop by the See beck effect.
